(19) United States
(12) Patent Application Publication
(10) Pub. No.: US 2026/0126470 A1
(43) Pub. Date: May 7, 2026

(54) DYNAMIC PROBE COLORING AND STATUS INFORMATION USING PASSIVE OPTICAL FIBER

(71) Applicant: Tektronix, Inc., Beaverton, OR (US)

(72) Inventors: Jackson R. Brooke, Beaverton, OR (US); Jeffrey D. Miller, Portland, OR (US); Barton T. Hickman, Portland, OR (US)

(73) Assignee: Tektronix, Inc., Beaverton, OR (US)

(21) Appl. No.: 19/383,514

(22) Filed: Nov. 7, 2025

Related U.S. Application Data
(60) Provisional application No. 63/717,791, filed on Nov. 7, 2024.

(51) Int. Cl. G01R 1/20; G01R 1/073

(52) U.S. Cl. CPC G01R 1/20; G01R 1/073

(57) ABSTRACT

A probe may include a probe head with a probe tip for connecting to a device under test (DUT), and a probe body for electro-mechanically connecting to a channel of a test and measurement instrument, the channel having a pre-assigned color identifier. The probe may include a probe cable connected between the probe head and the probe body. The probe may include a light source, and an optical fiber having a first end coupled to the light source and a second end coupled to the probe head. The probe head has a channel indicator coupled to the optical fiber. The probe has communication and control circuitry configured to, when the probe is connected to the channel of the test and measurement instrument, cause the light source and the channel indicator to illuminate in a color matching the color identifier of the channel.

### CROSS-REFERENCE TO RELATED APPLICATION

This application is a non-provisional of, and claims priority to, U.S. Provisional Pat. App. No. 63/717,791, filed Nov. 7, 2024, which is hereby incorporated by reference in its entirety.

### TECHNICAL FIELD

This disclosure relates to test and measurement systems, and more particularly to test and measurement probes.

### BACKGROUND

Test and measurement probe users often have multiple probes connected to a device under test (DUT) for measuring various signals. The other ends of the probes are each connected to different input channels of a test and measurement instrument, such as an oscilloscope. The signal received at each channel of the instrument is typically presented on the instrument's display in a unique assigned color or style, so a user can easily visually distinguish the different displayed signals. For example, the signal received at channel one of the instrument may be displayed in a yellow color, the signal received at channel two of the instrument may be displayed in blue, channel three in red, channel four in green, etc. When several probes are connected to a DUT, their cables can easily get tangled, especially if the probes are moved from one test point to another, and it can be difficult to visually determine which probe is physically connected to which input on the test and measurement instrument. To help users associate a probe with the channel to which it is connected, currently, some probe manufacturers include small plastic color rings with passive probes to allow users to associate the probe head and probe body. A similar approach can be taken for probes in other categories, but all solutions today require manual installation.

### BRIEF DESCRIPTION OF THE DRAWINGS

FIG. 1 is a diagram of plastic colored rings sometimes used for probe identification.

FIG. 2 is a block diagram of a test and measurement probe connected to a first channel of a test and measurement instrument, according to embodiments of the disclosure.

FIG. 3 is a block diagram of a test and measurement probe connected to a second channel of a test and measurement instrument, according to embodiments of the disclosure.

FIG. 4 is a block diagram of a test and measurement probe according to some embodiments of the disclosure.

FIG. 5 is a block diagram of a test and measurement probe according to some embodiments of the disclosure.

FIG. 6 is a block diagram of a test and measurement probe according to some embodiments of the disclosure.

FIG. 7 is a block diagram of a test and measurement probe according to some embodiments of the disclosure.

### DETAILED DESCRIPTION

Test and measurement probes can be divided into two categories: active and passive. Active probes use circuit components in the probe that require external power. Passive probes do not. For example, active probes typically include a powered component such as an amplifier, usually located as physically close to the probe tip/probing point as possible. In contrast, passive probes typically include only passive circuit components such as resistors and capacitors, especially at the probe tip. Some passive probes do include some powered components in the probe body, or “compbox” end that connects to the test and measurement instrument. For example, a memory device, such as an EEPROM, and some communication circuitry may be located in the probe body. The memory device can store an identifier of the probe type, such as a model number, and/or other attributes of the probe, such as an attenuation factor. When the probe is connected to the test and measurement instrument, power may be supplied through the connection interface from the test and measurement instrument to communication circuitry in the compbox to, for example, read the memory device. This allows the test and measurement instrument to recognize the probe type, and/or probe attribute, and automatically apply particular settings appropriate for that probe, for example vertical gain/scale settings, unit of measure settings, bandwidth limit, etc. Active probes generally provide higher bandwidth, higher performance, lower input impedance, and lower circuit loading than passive probes. However, passive probes are simpler, rugged, and lower cost, and are therefore quite suitable for general purpose DUT probing needs.

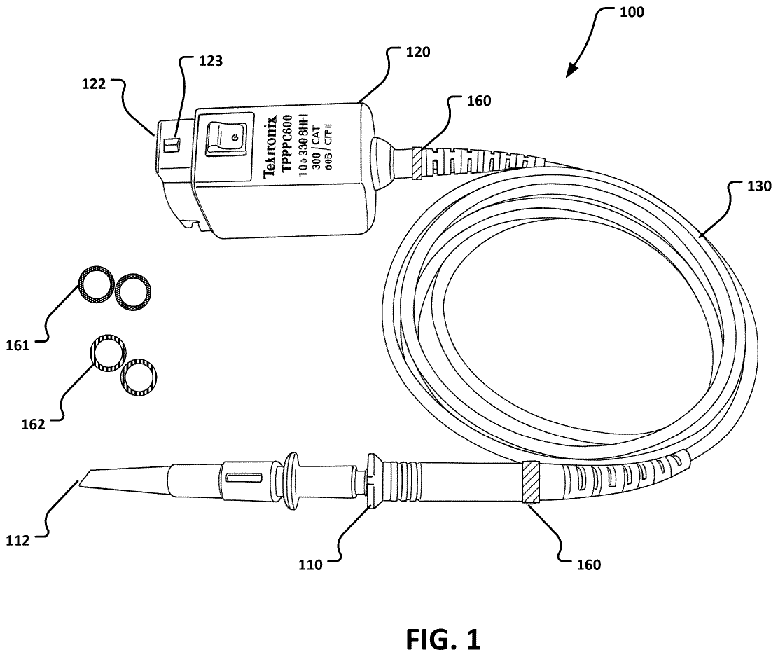

FIG. 1 shows an example of the plastic rings 160, 161, 162 currently used with some passive probes, intended to associate the probe head at one end of the cable with the probe body at the other. The probe 100 of FIG. 1 has a probe head 110 with a probe tip 112 extending from the probe head to make electrical contact with a test point on a DUT. The probe head is connected to a probe body 120 by a probe cable 130. The probe cable is typically a coaxial cable between 1 meter and 3 meters long, but other cable types and lengths are possible. The probe body 120 is the part of the probe that connects to a test and measurement instrument, for example connecting to an input channel on an oscilloscope, through a connection interface 122. The connection interface 122 may include an electrical connector, for example a Bayonet Neill-Concelman (BNC) connector, to convey the signal from the DUT to the connected test and measurement instrument, as well as one or more additional pins or other connectors to send and receive power, communications, and/or control signal between the probe and the connected instrument. The connection interface may also include mechanical connection features, such as the locking mechanism 123, so that the connection interface electro-mechanically connects the probe 100 to the test and measurement instrument.

FIG. 1 shows three different pairs of colored plastic rings 160, 161, 162. For example, plastic rings 160 may be colored yellow, as represented by the diagonal hatch pattern. The pair of plastic rings 161 may be colored green, as represented by the dotted hatch pattern. The pair of plastic rings 162 may be colored blue, as represented by the vertical hatch pattern. Each channel of the connected test and measurement instrument has an assigned color that matches one of the pairs of colored plastic rings 160, 161, 162. The assigned color for the channel is typically painted on the front panel of the instrument adjacent to the channel's input connector. An acquired waveform of a signal being received on that channel is also displayed on the instrument's screen in the same assigned color. For example, channel one of the instrument may be assigned the color yellow. Yellow is shown on the instrument's front panel, and the channel one waveform trace is displayed on the instrument screen in yellow. The user of probe 100 has to manually install the plastic rings of the color matching the channel to which the probe is connected. For example, the probe 100 in FIG. 1 has had the yellow plastic rings 160 installed, indicating that the probe is, or will be, connected to channel one of the instrument. As shown in FIG. 1, the user installs one ring 160 of the pair on the probe head (or probe tip) end of the probe (i.e. the end of the probe that connects to the DUT), and a second ring 160 of the pair on the probe body (or “compbox”) end of the probe (i.e. the end of the probe that connects to the test and measurement instrument). However, if the probe 100 is moved from channel one to a different channel of the instrument, the user would have to manually remove the plastic rings 160, and manually install one of the other pairs of plastic rings 161, 162.

Embodiments of this disclosure vastly improve the user experience with probing and identifying which probe is connected to which channel of a test and measurement instrument.

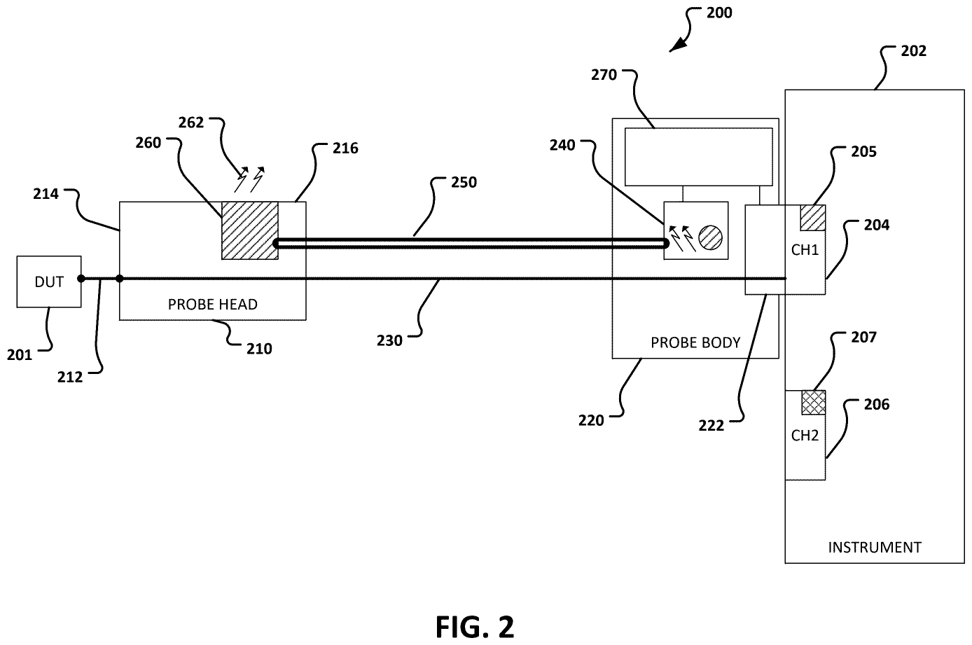

FIG. 2 is a block diagram of a test and measurement probe 200, according to some embodiments of the disclosure. The probe 200 is used to convey a signal of interest from a device under test (DUT) 201 to a test and measurement instrument 202, such as an oscilloscope, for example. The test and measurement instrument may have multiple channels, such as channel one 204, and channel two 206. Each channel 204, 206 has a pre-assigned color identifier. For example, channel one 204 may be assigned the color yellow, represented by the color patch 205 with the diagonal hatch pattern, and channel two 206 may be assigned the color blue, represented by the color patch 207 with the diagonal cross-hatch pattern. The color patches 205, 207 may be painted on the instrument's front panel adjacent to the input connector for the associated channel 204, 206, and the acquired waveforms of signals received on each channel are displayed on the instrument in the channel's assigned color.

As shown in FIG. 2, the test and measurement probe 200 may include a probe head 210. The probe head 210 may have a housing to enclose components of the probe head, which may be, in the case of a passive probe, a voltage divider RC network, for example, or which may be, in the case of an active probe, an amplifier, for example. The probe head may also include a probe tip 212 for electrically connecting to a DUT. The probe tip 212 may extend from the probe head to connect to the DUT in numerous ways such as through one or more connectors, e.g. BNC, Sub-Miniature Type-A (SMA), MMCX, etc., by being semi-permanently connected to a test point on the DUT using solder and wires, e.g. for a so-called “solder-down” style probe, by being temporarily placed by a user into physical contact with a test point on the DUT, e.g. for a so-called “browser” style probe, etc. The probe tip 212 may include multiple electrical contacts, such as a signal lead and a ground lead, or in the case of a differential probe, two signal leads to connect to both sides of a differential signal.

The test and measurement probe 200 may also include a probe body 220. The probe body includes a connection interface 222 for electro-mechanically connecting the probe to a channel of the test and measurement instrument 202. As shown in FIG. 1, the probe 200 is connected to channel one 204 of the instrument. Each channel 204, 206 of the instrument has a pre-assigned color identifier 205, 207. Color identified 205, which is yellow in this example, is pre-assigned to channel one 204. Color identifier 207, which is blue in this example, is pre-assigned to channel two 206. Connection interface 222 is similar to connection interface 122 discussed above in that connection interface 222 may include one or more connectors for conveying a signal probed by probe tip 212 to the connected channel of the instrument 202, as well as one or more additional signal lines to carry communication, control, and power signals between the probe 200 and the instrument 202.

The test and measurement probe 200 may also include a probe cable 230. The probe cable 230 is connected between the probe head and the probe body. The probe cable has a length, which is typically between 1 meter and 3 meters, but other lengths are possible. Embodiments of the disclosure may be especially useful in configurations where the probe cable is very long. Long cables allow using the probe in applications such as where the DUT is inside of a temperature chamber for testing, but the test and measurement instrument is outside the chamber. The long cable length allows the probe to reach the DUT, but also increases the difficulty of visually identifying what instrument channel the probe is connected to, especially when there are multiple probes connected to multiple different channels. Embodiments of the disclosure enable mush easier visual identification, especially when a user is near the DUT, and far away from the instrument 202. Ideally, the probe cable 230 should be highly flexible to allow a user to bend and route the probe cable around other test equipment, circuit components, etc. to have the probe tip 212 reach the test point of interest on the DUT. The probe cable 230 may be coaxial, but is not limited to coaxial, and other cable types are possible, including triax, twinax, twisted pair, etc.

The probe cable 230 conveys the signal from the DUT connected to the probe tip 212 from the probe head 210, through the probe 200, to the probe body 220, where it is then sent through connection interface 222 to the connected channel of the instrument. This discussion uses example embodiments of the disclosure that include a probe for acquiring a signal from a DUT and conveying that signal to an input channel of a test and measurement instrument, such as an oscilloscope. However, embodiments of the disclosure are not limited to this configuration. Embodiments of the disclosure could also be used with a test and measurement instrument 202 that produces an output signal, such as an arbitrary waveform generator (AWG), and therefore the probe 200 would be connected to an output channel of the instrument 202 and used to provide a signal output through the probe tip 212 to the DUT. In still other embodiments, the probe 200 and the instrument 202 may both send and receive signals on the same channel, for example with time-domain reflectometry (TDR) applications.

The test and measurement probe 200 also includes a light source 240, an optical fiber 250, and a channel indicator 260. According to some embodiments, the light source 240 is located in the probe body 220. The light source 240 may be, for example, a light emitting diode (LED). According to some embodiments, the light source 240 is a multi-color or full spectrum LED. The optical fiber 250 has a first end coupled to the light source 240, and a second end coupled to the probe head 210. Therefore, light from the light source 240 travels through the optical fiber 250 to the probe head 210. The optical fiber 250 is structured to run substantially parallel to the probe cable 230. Hence, the optical fiber 250 has approximately the same length as the probe cable 230. And, the optical fiber should be sufficiently flexible to bend and be routed together with the probe cable 230. According to some embodiments, the probe 200 may include multiple optical fibers 250, each coupled between the light source 240 and the probe head 210.

The optical fiber 250 is a passive optical fiber. By using passive optical fiber to pass light from the probe body to the probe head, no active circuitry, communication, or power is needed in the probe head, making embodiments of the disclosure useable with all types of probes, including passive probes. Accordingly, in some embodiments, the probe head comprises only passive components, because the channel indicator does not require electrical power in the probe head to operate. As discussed above, active probes typically would have a power line included in the probe cable to supply power to any active components, such as an amplifier, in the probe head. This power could possibly be used to power a light source located in the probe head. However, embodiments of the disclosure, because they only require the light being passed through optical fiber 250, still provide the advantage of simplifying the design of the probe head electronics, even for active probes.

The channel indicator 260 is located in the probe head 210 and is coupled to the second end of the optical fiber 250. The channel indicator 260 is structured to be visible to a user at an exterior surface, e.g. surface 216, of the housing of the probe head.

The probe 200 also includes communication and control circuitry 270, which in some embodiments may be located in the probe body 220. The communication and control circuitry 270 is configured to, when the connection interface 222 is connected to a channel, e.g. channel one 204, of the test and measurement instrument 202, cause the light source 240 to illuminate in a color matching the pre-assigned color identifier of the channel. Since the light source 240 is optically coupled through the optical fiber 250 to the channel identifier 260 in the probe head 210, this also causes the channel identifier 260 to illuminate in the color matching the color identifier of the connected channel. For example, as illustrated in FIG. 1, the probe 200 is connected to channel one 204 of the instrument 202. Channel one 204 has pre-assigned color identifier 205, yellow in this example, represented by the diagonal hatch pattern of 205. When the probe 200 is connected to channel one 204, the communication and control circuitry 270 causes the light source 240 to illuminate in the color yellow to match the pre-assigned channel one color identifier 205, as represented by the circle with diagonal hatch pattern shown inside element 240. This yellow light travels through optical fiber 250 to also illuminate channel indicator 260 in the color yellow, as represented by the diagonal hatch pattern shown in element 260. The colored light 262 from the channel indicator 260 is visible external to the probe 200 to allow a user to readily identify the channel to which the probe is connected.

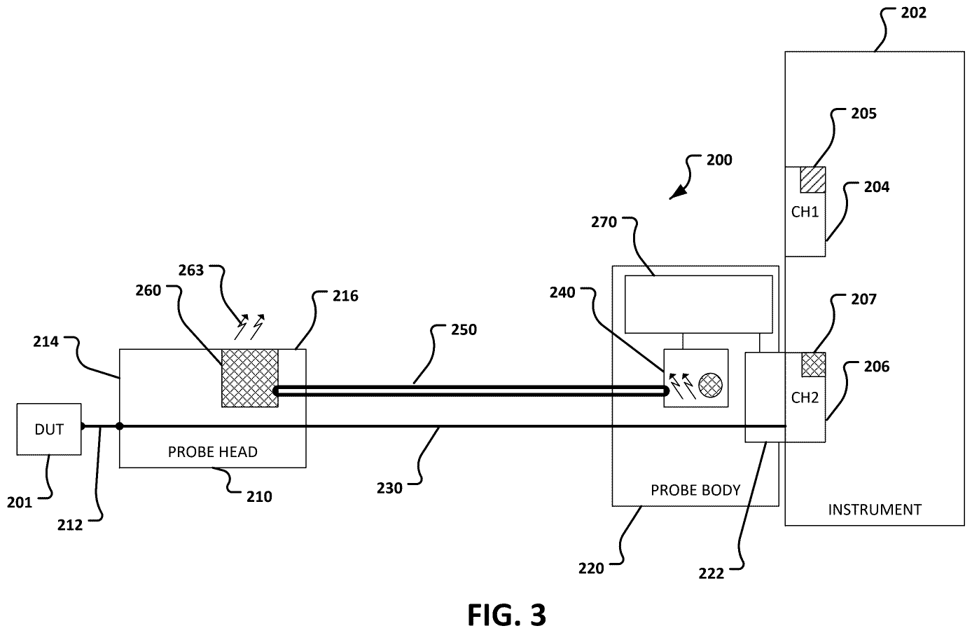

As shown in FIG. 3, if the probe 200 is disconnected from channel one 204 and connected to channel two 206 of the instrument 202, the communication and control circuitry causes the light source 240 to illuminate in a color that matches the color identifier 207 of channel two, which in this example is blue, represented by the diagonal cross-hatch pattern. The blue light from the light source 240 travels through the optical fiber 250 to also cause the channel indicator 260 in the probe head to illuminate in blue. The blue light 263 is visible to the probe user so the probe user can readily identify that the probe is now connected to channel two.

The optical fiber 250 is terminated in the probe head 210 at the channel indicator 260. For a visually pleasing display, in some embodiments, the channel indicator 260 comprises an optical diffuser to diffuse the light transmitted through the optical fiber. According to some embodiments, the optical diffuser may comprise a translucent portion of the housing of the probe head, such as a translucent window in the housing. so that the light 262, 263 passes through the translucent portion to be visible to a user. According to some embodiments, the translucent portion of the housing may comprise a translucent ring around a perimeter of the probe head housing. This ensures that the channel indicator is visible from nearly all viewing angles. As an example, a probe head according to one of these embodiments may have the similar appearance as the probe head 110 shown in FIG. 1, except that the static-colored plastic ring 160 on the probe head would instead be a translucent ring around the cylindrical probe head which would dynamically change color as the probe is connected to different channels. Although the probe head 110 has a circular longitudinal cross-section, the translucent “ring” does not necessarily have to be a circular ring, but could also be triangular, square or rectangle, another polygon, or any complex shape around a perimeter of the probe head.

According to some embodiments, the probe tip 212 may be located at a first exterior surface 214 of the housing of the probe head 210. The probe tip 212 may comprise a pin that protrudes from the exterior surface 214. The channel indicator 260 may then be located on one or more exterior surfaces 216 of the housing of the probe head that are different than the first exterior surface 214. For example, if the exterior surface 214 is the front surface of the probe head 210, the probe head housing may include an area on the side surfaces just behind the front surface intended for grasping by a user's fingers, then the channel indicator 260 may be located on one or more of the side surfaces behind the grasping area, and/or on the back surface of the probe head housing, so that the channel indicator is not obscured from view by the user's fingers when they are grasping the probe.

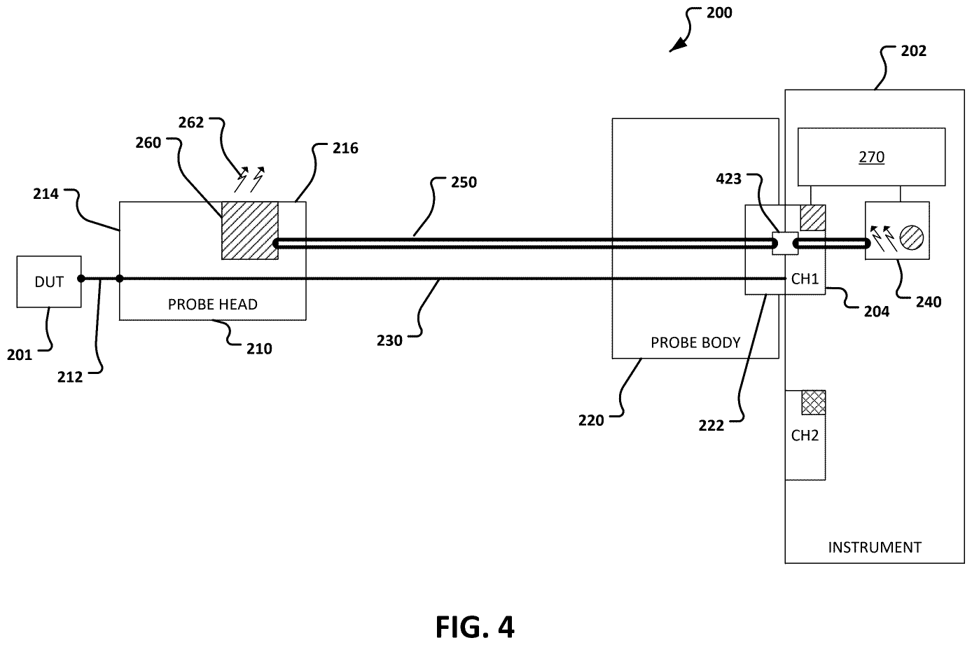

As shown in FIG. 4, according to some embodiments of the disclosure, the light source 240 may be located in the test and measurement instrument 202, rather than in the probe body 220. In these embodiments, the connection interface 222 may also include an optical connector 423 to couple the light source 240 to the optical fiber 250. In these embodiments, some portion of the communications and control circuitry 270 may also be located in the test and measurement instrument 202 rather than in the probe body 220.

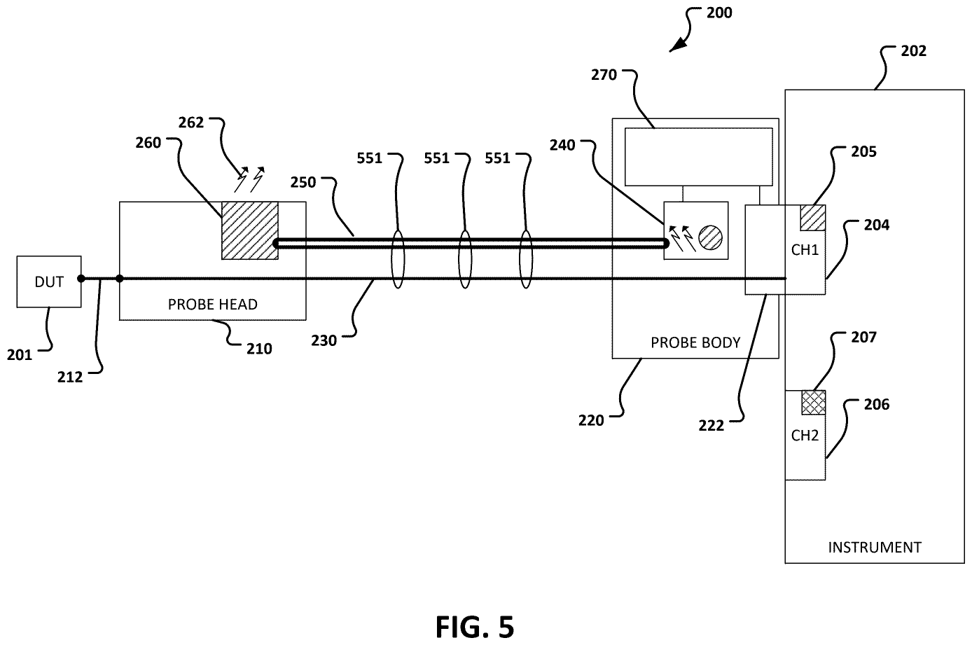

As discussed above, the optical fiber 250 runs substantially parallel to the probe cable 230. The optical fiber and the probe cable may be affixed to one another along the length of the probe cable so that, to a user, the optical fiber and the probe cable may appear to be a single cable. As shown in FIG. 5, in some embodiments, the optical fiber is mechanically connected to the probe cable at discrete locations 551 along the length of the probe cable. For example, the optical fiber may be connected to the probe cable at locations 551 using cable ties, adhesive, clips, or other components.

In other embodiments, the optical fiber 250 is mechanically connected to the probe cable 230 continuously along the length of the probe cable. For example, the optical fiber may be glued to the probe cable continuously along the length of the probe cable. Or, the probe cable may include a slot along the length of the probe cable, for example a slot in the probe cable's exterior cable jacket, into which the optical fiber can be inserted and retained.

According to some other embodiments of the disclosure, the fiber that is inserted into, embedded into, or otherwise mechanically bound to the probe cable can be at least partially exposed so that the at least some length of the probe cable between the probe body end and the probe head end becomes illuminated when the color LED in the probe body is illuminated. In some embodiments, the embedded fiber is exposed for the entire length of the probe cable, so that the entire length of the probe cable is illuminated when the probe body LED is illuminated. Illuminating the whole probe cable would enable very easy visual identification of which probe is connected to which instrument channel, easier detangling of multiple probe cables, as well as providing additional ambient illumination to the test environment and/or DUT.

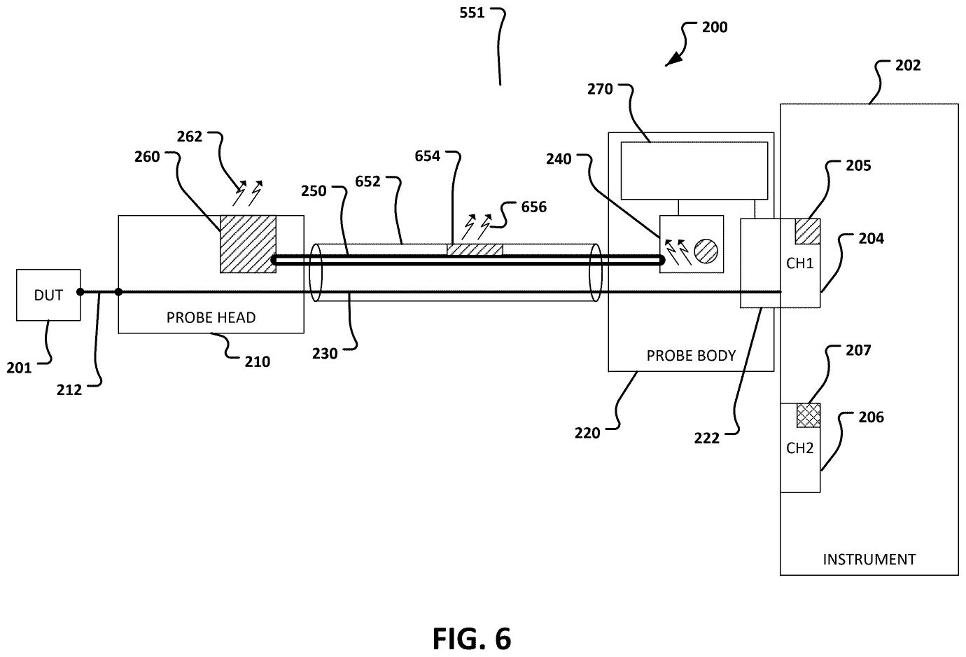

As shown in FIG. 6, according to some embodiments, the probe cable 230 and the optical fiber 250 are enclosed together in a common cable sleeve 652. The common cable sleeve 652 binds the probe cable 230 and the optical fiber 250 together so they move and bend together. The common cable sleeve 652 may be opaque. Or, in some embodiments, the common cable sleeve 652 may include one or more portions, such as portion 654 shown in FIG. 6, that are translucent. These translucent portions 654 of the common cable sleeve are positioned and configured allow a user to see the color of light passing through the optical fiber 250, since light 656 would be visible through the translucent portion 654. In the example shown in FIG. 6, the light 656 is yellow, represented by the diagonal hatch pattern in 654, to match the yellow channel one color indicator 205.

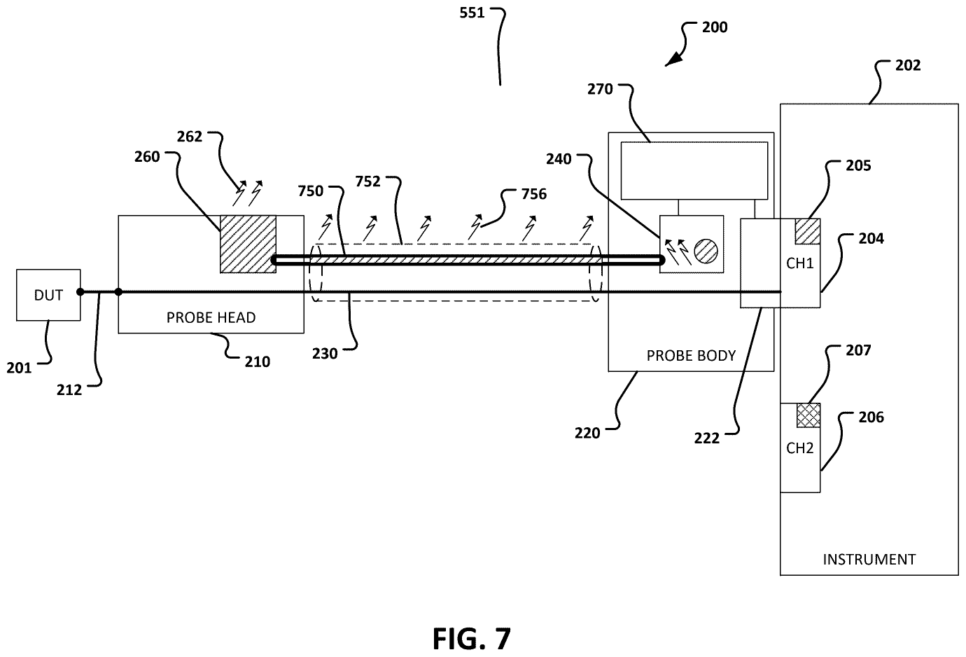

As shown in FIG. 7, according to some embodiments, at least a portion of the optical fiber 750 may be a light-diffusing fiber to enhance the amount of illumination 756 along the length of the fiber and probe cable 230. The fiber should be highly flexible to allow the probe cable to make relatively tight bends as expected by probe users. Examples of suitable light-diffusing fibers for use in some embodiments may include Coring Fibrace® Light-Diffusing Fiber and Ellumiglow Laser Wire® cable. In these embodiments, the light-diffusing fiber 750 is visible to a user of the probe. If a common cable jacket or sleeve 752 is used to bind the optical fiber to the probe cable, the common cable sleeve may be clear or translucent. As shown in FIG. 7, the entire length of the light-diffusing fiber would illuminate in the color that matches the color identifier of the channel to which the probe is connected, e.g. yellow for channel one. These embodiments make it easy for a user to visually identify, at any point on the probe between the probe body and the probe head, the channel to which the probe is connected. This may be particularly useful for detangling and rerouting multiple probe cables on a DUT.

According to some embodiments, multiple light-diffusing optical fibers may be inserted into the probe cable to illuminate the length of the cable. For example, one fiber may be inserted and partially exposed along a “top” surface of the probe cable, while a second fiber may be inserted and partially exposed along an opposite “bottom” surface of the probe cable. In other embodiments, three, four, or more fibers could be inserted into the probe cable. In still other embodiments, a single fiber can be used, and the probe cable jacket may be made of a clear or translucent material to allow the light-diffusing fiber to be visible.

According to some embodiments of the disclosure, the light source 240, optical fiber 250, and channel indicator 260 can also be used to communicate additional information to a user besides identifying the channel to which the probe is connected. In some embodiments, the communication and control circuitry is further configured to cause the light source to produce a pattern of light, to illuminate in a specific intensity, or to illuminate in a specific color in response to either an input from a user and/or an instruction from the test and measurement instrument.

For example, a user could press a button on the probe, or on the test and measurement instrument, that directs the circuitry 270 to cause the light source 240 to flash quickly. The light visible at the channel indicator 260 would then follow this same flashing pattern. This may be additionally helpful to a user in locating the probe head of the probe on a DUT, especially in dark environments, such as automotive testing, for example. Other light patterns such as a slow fade-in/fade-out, a dot-dash pattern like Morse code, or any other pattern of light may be used to communicate various information.

As another example, if the test and measurement instrument detects that the signal being received through the probe 200 is clipping at the instrument, the instrument could send an instruction that directs the circuitry 270 to cause the light source 240, and therefore the channel indicator 260, to illuminate in a specific color, such as bright red, for example, to visually indicate the clipping condition to a user.

As yet another example, if the instrument detects that the signal being received through the probe has an amplitude that occupies only 20% of full scale on the instrument's display, the instrument may instruct the circuitry 270 to cause the light source to illuminate to 20% of its full intensity. Thus, a small amplitude signal received by the probe would cause the light at the channel indicator 260 to be relatively dim, while a large amplitude signal received by the probe would cause the light at the channel indicator 260 to be relatively bright. Alternatively, signal amplitude could be visually communicated to a user by changing the color or light pattern. For example, small amplitude signals could cause the light at the channel indicator to be a relatively “cool” color such as blue, while large amplitude signals could cause the light at the channel indicator to be a relatively “warm” color such as red. Or, the light at the channel indicator could be caused to flash slowly for a small amplitude signal, and flash quickly or stay solidly illuminated for a large amplitude signal. These signal “temperature” colors or light patterns shown at the channel indicator could dynamically change as the amplitude of the received signal changes. This would give the user a DMM-like functionality, visually in colors, intensities, or patterns, right at the probe head.

As can be seen with these examples, many different combinations of specific colors, intensities, and/or light patterns may be used to communicate various probe or instrument error conditions, signal levels, thresholds, digital signal binary data, etc. to a user.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A test and measurement probe, comprising:
a probe head including a housing, and a probe tip for electrically connecting to a device under test (DUT);
a probe body including a connection interface for electro-mechanically connecting to a channel of a test and measurement instrument, the channel having a pre-assigned color identifier;
a probe cable connected between the probe head and the probe body, the probe cable having a length;
a light source;
an optical fiber having a first end coupled to the light source and a second end coupled to the probe head, the optical fiber running substantially parallel to the probe cable;
a channel indicator visible to a user at an exterior surface of the housing of the probe head, the channel indicator coupled to the optical fiber; and
communication and control circuitry configured to, when the connection interface is connected to the channel of the test and measurement instrument, cause the light source and the channel indicator to illuminate in a color matching the color identifier of the channel.

2. The test and measurement probe of claim 1, wherein the channel indicator comprises an optical diffuser.

3. The test and measurement probe of claim 2, wherein the optical diffuser comprises a translucent portion of the housing of the probe head.

4. The test and measurement probe of claim 3, wherein the translucent portion comprises a translucent ring around a perimeter of the housing of the probe head.

5. The test and measurement probe of claim 1, wherein the probe tip is located at a first exterior surface of the housing of the probe head, and the channel indicator is located on one or more exterior surfaces of the housing different than the first exterior surface.

6. The test and measurement probe of claim 1, wherein the probe head comprises only passive circuit components.

7. The test and measurement probe of claim 1, wherein the light source is located in the probe body.

8. The test and measurement probe of claim 1, wherein the light source is located in the test and measurement instrument, and the connection interface includes an optical connector to couple the light source to the optical fiber.

9. The test and measurement probe of claim 1, wherein the optical fiber comprises a plurality of optical fibers, each optical fiber having a first end coupled to the light source and a second end coupled to the probe head.

10. The test and measurement probe of claim 1, wherein the optical fiber is mechanically connected to the probe cable at discrete locations along the length of the probe cable.

11. The test and measurement probe of claim 1, wherein the optical fiber is mechanically connected to the probe cable continuously along the length of the probe cable.

12. The test and measurement probe of claim 1, wherein the probe cable includes a slot along the length of the probe cable, and the optical fiber is inserted into the slot.

13. The test and measurement probe of claim 1, wherein the probe cable and the optical fiber are enclosed together in a common cable sleeve.

14. The test and measurement probe of claim 13, wherein one or more portions of the common cable sleeve are translucent.

15. The test and measurement probe of claim 1, wherein at least a portion of the optical fiber comprises a light-diffusing fiber.

16. The test and measurement probe of claim 15, wherein the light-diffusing fiber is visible to a user.

17. The test and measurement probe of claim 1, wherein the communication and control circuitry is further configured to cause the light source to produce a pattern of light, to illuminate in a specific intensity, or to illuminate in a specific color in response to at least one of an input from a user and an instruction from the test and measurement instrument.

18. A method of visually identifying a test and measurement probe connected to a channel of a test and measurement instrument, the channel having a pre-assigned color identifier, the method comprising:
causing a light source to illuminate in a color matching the color identifier of the channel, the light source being coupled to a first end of an optical fiber in a probe body of the test and measurement probe, the optical fiber running substantially parallel to an electrical probe cable of the test and measurement probe;
transmitting the light from the light source through the optical fiber to a second end of the optical fiber in a probe head of the test and measurement probe; and
diffusing the light at the probe head so that the color is visible to a user at the probe head.

19. The method of claim 18, wherein transmitting the light from the light source comprises diffusing the light along at least a portion of a length of the optical fiber so that the light is visible to a user along the portion of the length.

20. The method of claim 18, further comprising:
causing the light source to produce a pattern of light, to illuminate in a specific intensity, or to illuminate in a specific color in response to at least one of an input from the user and an instruction from the test and measurement instrument.
